(19) United States
(12) Patent Application Publication
(10) Pub. No.: US 2021/0251107 A1
(43) Pub. Date: Aug. 12, 2021

(54) VAPOR CHAMBER STRUCTURE AND MANUFACTURING METHOD THEREOF

(71) Applicant: Unimicron Technology Corp., Taoyuan City (TW)

(72) Inventors: Ra-Min Tain, Hsinchu County (TW); Pu-Ju Lin, Hsinchu City (TW); Cheng-Chung Lo, Hsinchu County (TW); Chi-Hai Kuo, Taoyuan City (TW); Cheng-Ta Ko, Taipei City (TW); Tzyy-Jang Tseng, Taoyuan City (TW); John Hon-Shing Lau, Taoyuan City (TW)

(73) Assignee: Unimicron Technology Corp., Taoyuan City (TW)

(21) Appl. No.: 17/017,702

(22) Filed: Sep. 11, 2020

Related U.S. Application Data
(60) Provisional application No. 62/972,050, filed on Feb. 9, 2020.

(30) Foreign Application Priority Data
Jul. 14, 2020 (TW) 109123680

(51) Int. Cl. H05K 7/20; F28D 15/02; F28D 15/04; B21D 53/08

(52) U.S. Cl. CPC H05K 7/20336; F28D 15/0275; G06F 1/203; F28D 15/0233; B21D 53/08; F28D 15/046

(57) ABSTRACT

A vapor chamber structure includes a thermally conductive housing, a capillary structure layer, a grid structure layer, and a working fluid. The thermally conductive housing has a sealed chamber, where a pressure in the sealed chamber is lower than a standard atmospheric pressure. The capillary structure layer is disposed in the sealed chamber. The grid structure layer is disposed in the sealed chamber and arranged along a first direction. A size of the grid structure layer is less than or equal to a size of the capillary structure layer. The working fluid fills the sealed chamber.

### CROSS-REFERENCE TO RELATED APPLICATION

This application claims the priority benefit of U.S. provisional application Ser. No. 62/972,050, filed on Feb. 9, 2020, and Taiwan application serial no. 109123680, filed on Jul. 14, 2020. The entirety of each of the above-mentioned patent applications is hereby incorporated by reference herein and made a part of this specification.

### BACKGROUND OF THE INVENTION

### 1. Field of the Invention

The invention relates to a thermally conductive structure and a manufacturing method thereof, and in particular, to a vapor chamber structure and a manufacturing method thereof.

### 2. Description of Related Art

A current vapor chamber is mostly used on an outer edge of an electronic system and between an electronic component or a circuit board and a heat sink. Because a size and a thickness of the vapor chamber are mostly above 1 mm, it is difficult to place the vapor chamber in, for example, a mobile phone housing, thereby limiting an application scope of the vapor chamber. In addition, because an outer layer of the vapor chamber is made of a polymer material, the heat dissipation coefficients of the polymer material and the metallic copper differ by two orders, and a structure of a thermal conductive material layer in the vapor chamber is complicated and production costs are high. Therefore, how to effectively reduce a thickness of the vapor chamber, effectively reduce the production costs, and simplify a manufacturing process becomes one of problems to be resolved urgently.

### SUMMARY OF THE INVENTION

The invention provides a vapor chamber structure, which has an advantage of thinner thickness.

The invention further provides a method for manufacturing the vapor chamber structure, which is used to manufacture the above-mentioned vapor chamber structure, which has advantages of simple manufacturing, thin thickness, and low costs.

The vapor chamber structure of the invention includes a thermally conductive housing, a capillary structure layer, a grid structure layer, and a working fluid. The thermally conductive housing has a sealed chamber, where a pressure in the sealed chamber is lower than a standard atmospheric pressure. The capillary structure layer is disposed in the sealed chamber. The grid structure layer is disposed in the sealed chamber and arranged along a first direction. A size of the grid structure layer is less than or equal to a size of the capillary structure layer. The working fluid fills the sealed chamber.

In an embodiment of the invention, the thermally conductive housing is formed by sealing a folded thermally conductive material sheet.

In an embodiment of the invention, a size of the grid structure layer is less than or equal to half of a size of the capillary structure layer.

In an embodiment of the invention, the capillary structure layer includes a first capillary structure portion, a second capillary structure portion, and a third capillary structure portion. The sealed chamber has a top wall and a bottom wall opposite to each other, and a side wall connecting the top wall to the bottom wall. The first capillary structure portion is located on the top wall, the second capillary structure portion is located on the bottom wall, and the third capillary structure portion is located on the side wall. The grid structure layer is sandwiched between the first capillary structure portion and the second capillary structure portion.

In an embodiment of the invention, the thermally conductive housing is formed by sealing a first thermally conductive material sheet and a second thermally conductive material sheet that overlap each other.

In an embodiment of the invention, a size of the grid structure layer is less than or equal to half of a size of the capillary structure layer.

In an embodiment of the invention, the capillary structure layer includes a first capillary structure portion and a second capillary structure portion. The sealed chamber has a top wall and a bottom wall opposite to each other. The first capillary structure portion is located on the top wall, the second capillary structure portion is located on the bottom wall, and the grid structure layer is sandwiched between the first capillary structure portion and the second capillary structure portion.

In an embodiment of the invention, the capillary structure layer is a surface microstructure layer of the thermally conductive housing.

In an embodiment of the invention, the capillary structure layer is a mesh structure layer, and a hole of the mesh structure layer is smaller than a hole of the grid structure layer.

In an embodiment of the invention, a material of the mesh structure layer includes glass fiber, metal, ceramic, carbon, or organic plastic.

In an embodiment of the invention, the grid structure layer includes a plurality of fluid channels. The fluid channels are arranged on a same plane at equal intervals along the first direction.

In an embodiment of the invention, the grid structure layer includes a plurality of fluid channels. The fluid channels are arranged on different planes in a matrix along the first direction and a second direction perpendicular to the first direction.

In an embodiment of the invention, a material of the grid structure layer includes glass fiber, metal, ceramic, carbon, or organic plastic.

In an embodiment of the invention, the working fluid includes water.

In an embodiment of the invention, a material of the thermally conductive housing includes metal or ceramic.

A method for manufacturing the vapor chamber structure includes the following steps. A thermally conductive material sheet is provided, where the thermally conductive material sheet has a configuration region and a peripheral region surrounding the configuration region. A capillary structure layer is formed on the configuration region of the thermally conductive material sheet. A grid structure layer is formed on the capillary structure layer, where a size of the grid structure layer is less than or equal to half of a size of the capillary structure layer. The thermally conductive material sheet is folded in half to cause the grid structure layer and the capillary structure layer to be sandwiched between a first part and a second part of the thermally conductive material sheet. After folding the thermally conductive material sheet in half, a peripheral region of the thermally conductive material sheet is sealed to form a chamber C, where the grid structure layer and the capillary structure layer are located in the chamber. A vacuuming process is performed on the chamber, and a working fluid is provided in the chamber. The chamber is completely sealed to form a sealed chamber and cause the working fluid to fill the sealed chamber.

In an embodiment of the invention, the thermally conductive material sheet has a first side and a second side opposite to each other, and two flaps. The two flaps are respectively connected to the first side and the second side and disposed corresponding to each other, and the configuration region is connected to the two flaps. The vacuuming process is performed on the chamber from a space between the two flaps and the working fluid is provided in the chamber from the space between the two flaps. The space between the two flaps is sealed to completely seal the chamber.

In an embodiment of the invention, the method for forming the capillary structure layer includes performing an etching process, an electroplating process, a printing process, a laser process, or a sintering process on the thermally conductive material sheet to form the capillary structure layer on a surface of the thermally conductive material sheet.

In an embodiment of the invention, the capillary structure layer is a mesh structure layer, and a hole of the mesh structure layer is smaller than a hole of the grid structure layer.

In an embodiment of the invention, a material of the mesh structure layer includes glass fiber, metal, ceramic, carbon, or organic plastic.

In an embodiment of the invention, the grid structure layer includes a plurality of fluid channels. The fluid channels are arranged on a same plane at equal intervals or arranged on different planes in a matrix.

In an embodiment of the invention, a material of the grid structure layer includes glass fiber, metal, ceramic, carbon, or organic plastic.

In an embodiment of the invention, a method for completely sealing the chamber includes a mechanical clamping process, a diffusion bonding process, a welding process, a soft soldering process, or an adhering process.

In an embodiment of the invention, the working fluid includes water.

In an embodiment of the invention, a material of the thermally conductive material sheet includes metal or ceramic.

A method for manufacturing the vapor chamber structure includes the following steps. A first thermally conductive material sheet and a second thermally conductive material sheet are provided, where the first thermally conductive material sheet has a first configuration region and a first peripheral region surrounding the first configuration region, and the second thermally conductive material sheet has a second configuration region and a second peripheral region surrounding the second configuration region. A first capillary structure layer is formed in the first configuration region of the first thermally conductive material sheet, and a second capillary structure layer is formed in the second configuration region of the second thermally conductive material sheet. A grid structure layer is formed on the second capillary structure layer, where a size of the grid structure layer is less than a size of the second thermally conductive material sheet. The first thermally conductive material sheet is overlapped on the second thermally conductive material sheet to cause the grid structure layer to be sandwiched between the first capillary structure layer and the second capillary structure layer. After overlapping the first thermally conductive material sheet on the second thermally conductive material sheet, the first peripheral region of the first thermally conductive material sheet and the second peripheral region of the second thermally conductive material sheet are sealed to form a chamber, where the grid structure layer, the first capillary structure layer, and the second capillary structure layer are located in the chamber. A vacuuming process is performed on the chamber, and a working fluid is provided in the chamber. The chamber is completely sealed to form a sealed chamber and cause the working fluid to fill the sealed chamber.

In an embodiment of the invention, the first thermally conductive material sheet has a first flap, and the second thermally conductive material sheet has a second flap. When the first thermally conductive material sheet is overlapped on the second thermally conductive material sheet, the first flap is overlapped on the second flap. The vacuuming process is performed on the chamber from a space between the first flap and the second flap, and the working fluid is provided in the chamber from the space between the first flap and the second flap. The space between the first flap and the second flap is sealed to completely seal the chamber.

In an embodiment of the invention, the method for forming the first capillary structure layer and the second capillary structure layer includes respectively performing an etching process, an electroplating process, a printing process, a laser process, or a sintering process on the first thermally conductive material sheet and the second thermally conductive material sheet to form the first capillary structure layer on a first surface of the first thermally conductive material sheet, and form the second capillary structure layer on a second surface of the second thermally conductive material sheet.

In an embodiment of the invention, the grid structure layer includes a plurality of fluid channels. The fluid channels are arranged on a same plane at equal intervals or arranged on different planes in a matrix.

In an embodiment of the invention, a method for completely sealing the chamber includes a mechanical clamping process, a diffusion bonding process, a welding process, a soft soldering process, or an adhering process.

In an embodiment of the invention, a material of the grid structure layer includes glass fiber, metal, ceramic, carbon, or organic plastic.

In an embodiment of the invention, the working fluid includes water.

In an embodiment of the invention, a material of the first thermally conductive material sheet includes metal or ceramic.

In an embodiment of the invention, a material of the second thermally conductive material sheet includes metal or ceramic.

Based on the above, in the method for manufacturing the vapor chamber structure of the invention, the grid structure layer and the capillary structure layer are sandwiched between the first part and the second part of the thermally conductive material sheet by folding the thermally conductive material sheet. Next, the peripheral region of the thermally conductive material sheet is sealed to form the chamber, and the vacuuming process is performed on the chamber, and the working fluid is provided in the chamber. After that, the chamber is completely sealed to cause the working fluid to fill the sealed chamber. Therefore, the thermally conductive housing of the vapor chamber structure of the invention is manufactured through the thermally conductive material sheet, so that the vapor chamber structure of the invention may have a thinner thickness. In addition, the manufacturing of the vapor chamber structure of the invention is also relatively simple and low in cost.

To make the foregoing features and advantages of the present invention clearer and easier to understand, a detailed description is made below by using listed embodiments with reference to the accompanying drawings.

### BRIEF DESCRIPTION OF THE DRAWINGS

FIG. 1A to FIG. 1E are schematic diagrams of a method for manufacturing a vapor chamber structure according to an embodiment of the invention.

FIG. 1F is a schematic diagram of a vapor chamber structure according to an embodiment of the invention.

FIG. 1G is a schematic cross-sectional diagram of a vapor chamber structure according to an embodiment of the invention.

FIG. 2A and FIG. 2B are respectively a schematic three-dimensional diagram and a schematic top diagram of a grid structure layer of FIG. 1C.

FIG. 2C is a schematic three-dimensional diagram of a grid structure layer according to another embodiment of the invention.

FIG. 3A to FIG. 3D are schematic diagrams of partial steps of a method for manufacturing a vapor chamber structure according to another embodiment of the invention.

FIG. 3E is a schematic cross-sectional diagram of a vapor chamber structure according to an embodiment of the invention.

FIG. 4 is a schematic diagram of partial steps of a method for manufacturing a vapor chamber structure according to another embodiment of the invention.

FIG. 5A to FIG. 5F are schematic diagrams of a method for manufacturing a vapor chamber structure according to another embodiment of the invention.

FIG. 5G is a schematic cross-sectional diagram of a vapor chamber structure according to an embodiment of the invention.

FIG. 6A and FIG. 6B are a schematic top diagram and a schematic cross-sectional diagram of an electronic device by using the vapor chamber structure of the invention.

FIG. 6C is a schematic cross-sectional diagram of another electronic device by using the vapor chamber structure of the invention.

### DESCRIPTION OF THE EMBODIMENTS

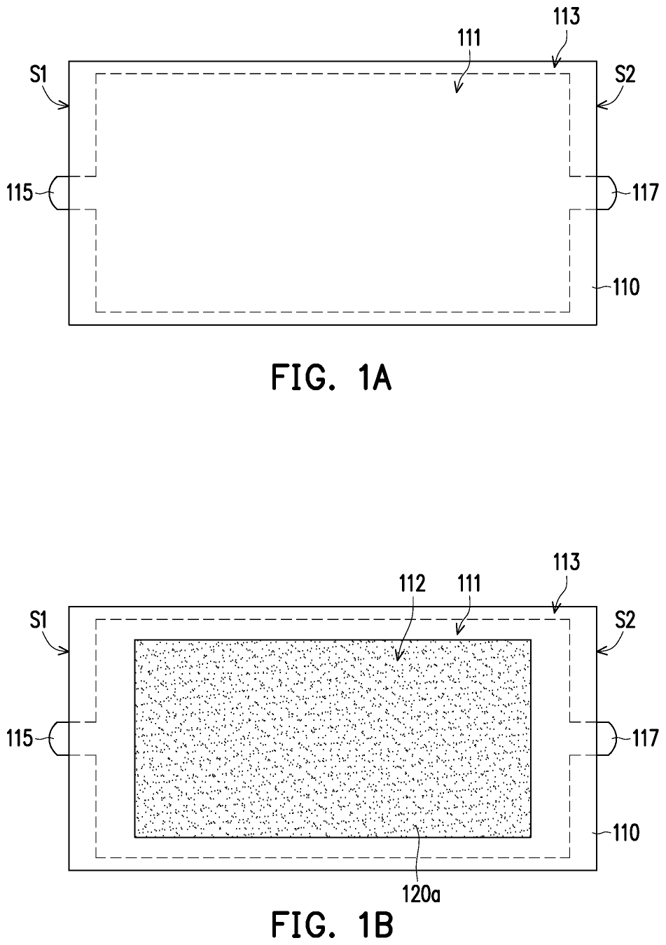

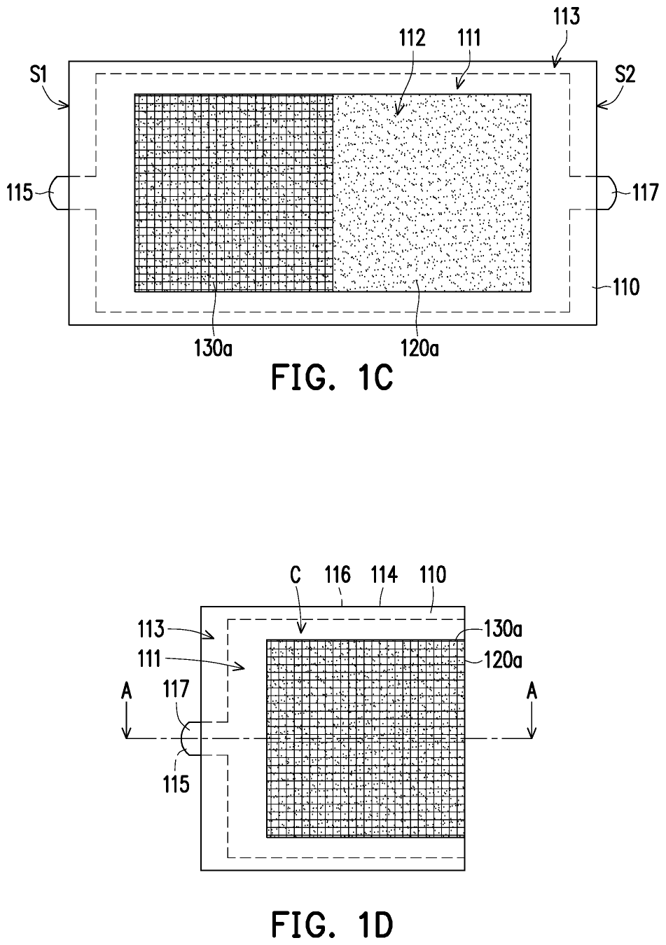

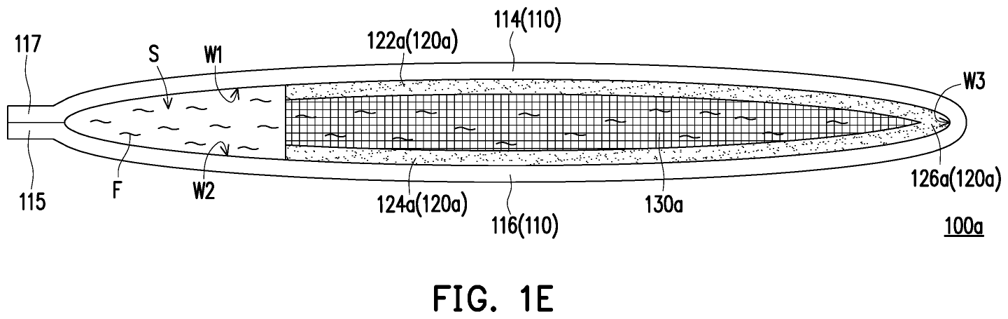

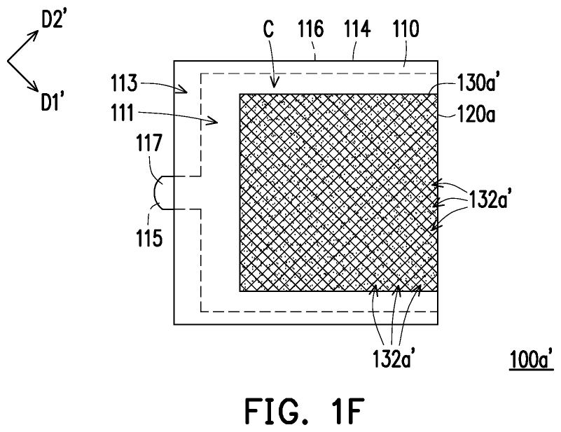

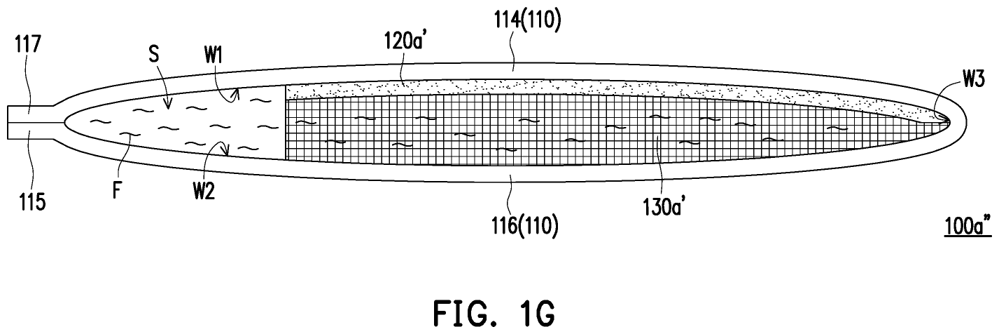

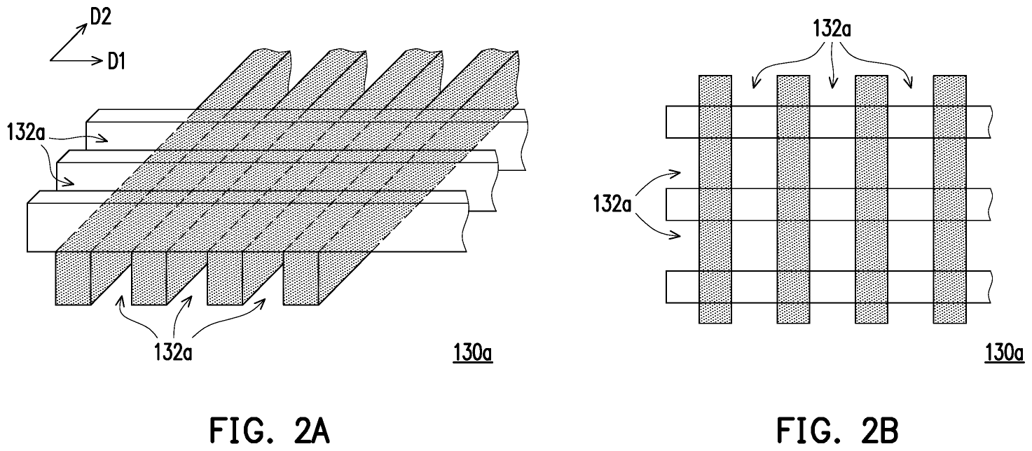

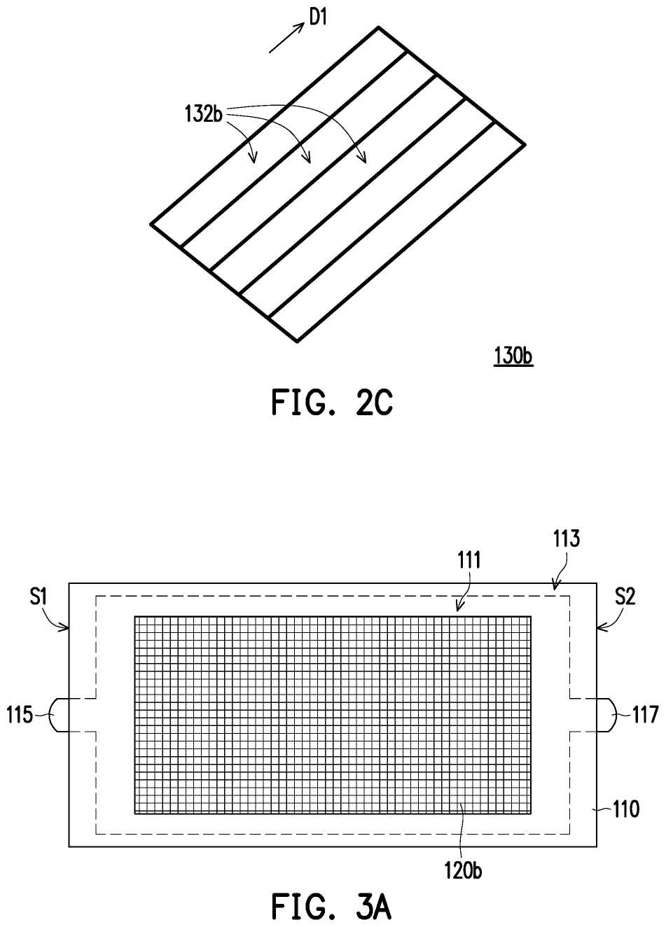

FIG. 1A to FIG. 1E are schematic diagrams of a method for manufacturing a vapor chamber structure according to an embodiment of the invention. FIG. 2A and FIG. 2B are respectively a schematic three-dimensional diagram and a schematic top diagram of a grid structure layer of FIG. 1C. FIG. 2C is a schematic three-dimensional diagram of a grid structure layer according to another embodiment of the invention. For the sake of convenience, FIG. 1D is shown in a partially perspective manner and FIG. 1E is a schematic cross-sectional diagram along a line A-A of FIG. 1D.

For a method for manufacturing a vapor chamber structure of the present embodiment, first, reference is made to FIG. 1A, in which a thermally conductive material sheet 110 is provided. The thermally conductive material sheet 110 has a configuration region 111 and a peripheral region 113 surrounding the configuration region 111. In detail, the thermally conductive material sheet 110 of the present embodiment has a first side S1 and a second side S2 opposite to each other, and two flaps 115 and 117. The flaps 115 and 117 are respectively connected to the first side S1 and the second side S2 and are disposed corresponding to each other, and the configuration region 111 is connected to the flaps 115 and 117. Herein, a material of the thermally conductive material sheet 110 is, for example, metal or ceramic. For example, if the material of the thermally conductive material sheet 110 is metal, such as copper, a thickness of the thermally conductive material sheet is about 50 microns. A length of the thermally conductive material sheet 110 is, for example, 0.01 meter to 0.1 meter, but the invention is not limited thereto.

Next, referring to FIG. 1B, a capillary structure layer 120a is formed in the configuration region 111 of the thermally conductive material sheet 110. Herein, a method for forming the capillary structure layer 120a is, for example, performing an etching process, an electroplating process, a printing process, a laser process, or a sintering process on the thermally conductive material sheet 110, to form the capillary structure layer 120a on a surface 112 of the thermally conductive material sheet 110. In another embodiment, the method for forming the capillary structure layer 120a may further be a surface treatment process, such as browning treatment or roughening treatment. In short, the capillary structure layer 120a of the present embodiment is embodied as a surface microstructure layer of the thermally conductive housing 110. Herein, a thickness of the capillary structure layer 120a is, for example, 8 microns to 30 microns, and an arithmetic average roughness (Ra) is 0.1 microns to 15 microns.

Next, referring to FIG. 1C, a grid structure layer 130a is formed on the capillary structure layer 120a. A size of the grid structure layer 130a is less than or equal to half of a size of the capillary structure layer 120a. Herein, the grid structure layer 130a may be a single-layer structure layer or a multi-layer structure layer, and the size includes a length, a width and an area. Further, referring to FIG. 2A and FIG. 2B, the grid structure layer 130a of the present embodiment includes a plurality of fluid channels 132a. The fluid channels 132a are arranged on different planes in a matrix, for example, the fluid channels 132a located on an upper plane are arranged along a first direction D1, the fluid channels 132a located on a lower plane are arranged along a second direction D2, and the first direction D1 is substantially perpendicular to the second direction D2, but the invention is not limited thereto. Herein, a material of the grid structure layer 130a includes glass fiber, metal, ceramic, carbon, or organic plastic, and a thickness of the grid structure layer 130 is, for example, 0.05 mm. It should be noted that the fluid channels 132a located on the upper plane and the fluid channels 132a located on the lower plane may be independent structures, or may be integrally formed structures, which are not limited herein. In addition, the first direction D1 may be parallel to a length direction (that is, an X axis) of the thermally conductive material sheet 110, and the second direction D2 may be parallel to a width direction (that is, a Y axis) of the thermally conductive material sheet 110, but the invention is not limited thereto.

In another embodiment, referring to FIG. 2C, fluid channels 132b of a grid structure layer 130b may further be arranged along a first direction D1 and arranged on a same plane at equal intervals, which still belongs to a protective scope of the invention. It should be noted that a material of the grid structure layer 130b herein may be, for example, stainless steel with a diameter of 0.05 mm, and a width (that is, grid spacing) of the fluid channel 132b is 1 mm to 2 mm, which may be formed through welding, etching, or mechanical milling. Alternatively, the material of the grid structure layer 130b may be, for example, copper foil with a diameter of 0.05 mm, and the width (that is, the grid spacing) of the fluid channel 132b is 1 mm to 2 mm, which may be formed through etching or mechanical milling.

Later, referring to both FIG. 1D and FIG. 1E, the thermally conductive material sheet 110 is folded in half, so that the grid structure layer 130a and the capillary structure layer 120a are sandwiched between a first part 114 and a second part 116 of the thermally conductive material sheet 110. Herein, after the thermally conductive material sheet 110 is folded in half, the first part 114 and the second part 116 may be completely aligned with each other, and the flap 115 may completely overlap the flap 117.

Next, referring to both FIG. 1D and FIG. 1E, after the thermally conductive material sheet 110 is folded in half, the peripheral region 113 of the thermally conductive material sheet 110 is sealed to form a chamber C. Herein, the grid structure layer 130a and the capillary structure layer 120a are located in the chamber C, and only a position at which the flaps 115 and 117 are vertically overlapped and a part of the configuration region 111 are not sealed. Herein, the sealing the peripheral region 113 of the thermally conductive material sheet 110 may include a mechanical clamping process, a welding process, a soft soldering process, a diffusion bonding process, or an adhering process. After that, a vacuuming process is performed on the chamber C, and a working fluid F is provided in the chamber C. More particular, the vacuuming process is performed on the chamber C from a space between the two flaps 115 and 117, and the working fluid F is provided in the chamber C from the space between the two flaps 115 and 117. Finally, the chamber C is completely sealed to form a sealed chamber S, and cause the working fluid F to fill the sealed chamber S. Herein, the chamber C is completely sealed by sealing the space between the two flaps 115 and 117, so that the sealed chamber S is formed. Herein, a method for completely sealing the chamber C includes a mechanical clamping process, a welding process, a soft soldering process, or an adhering process, and the working fluid F is, for example, water. So far, the method for manufacturing the vapor chamber structure 100a is completed.

In terms of the structure, still referring to FIG. 1E, the vapor chamber structure 100a of the present embodiment includes a thermally conductive housing formed by sealing the folded heat conductive material sheet 110, the capillary structure layer 120a, the grid structure layer 130a, and the working fluid F. The thermally conductive housing has the sealed chamber S, and the pressure in the sealed chamber S is lower than the standard atmospheric pressure.

Therefore, a boiling temperature of the working fluid F (for example, water) herein is about 60° C. Herein, a material of the thermally conductive housing is, for example, metal or ceramic. The capillary structure layer 120a is embodied as a surface microstructure of the thermally conductive housing, is disposed in the sealed chamber S, and includes the first capillary structure portion 122a and the second capillary structure portion 124a to transport the working fluid F through a capillary phenomenon. The sealed chamber S has a top wall W1 and a bottom wall W2 opposite to each other, the first capillary structure portion 122a is located on the top wall W1, and the second capillary structure portion 124a is located on the bottom wall W2. Further, the capillary structure layer 120a of the present embodiment further includes a third capillary structure portion 126a, and the sealed chamber S has a side wall W3 connecting the top wall W1 to the bottom wall W2, and the third capillary structure portion 126a is located on a side wall W3. The grid structure layer 130a is disposed in the sealed chamber S and sandwiched between the first capillary structure portion 122a and the second capillary structure portion 124a, to prevent the top wall W1 from directly contacting the bottom wall W2, and allow the working fluid F to pass. A size of the grid structure layer 130a is less than or equal to half of a size of the capillary structure layer 120a, and a material of the mesh structure layer 130a includes glass fiber, metal, ceramic, carbon, or organic plastic. The working fluid F fills the sealed chamber S, and the working fluid F is, for example, water. Preferably, an overall thickness of the vapor chamber structure 100a of the present embodiment is less than 300 microns, preferably, less than or equal to 0.25 mm.

In the method for manufacturing the vapor chamber structure 100a of the present embodiment, the grid structure layer 130a and the capillary structure layer 120a are sandwiched between the first part 114 and the second part 116 of the thermally conductive material sheet 110 by folding the thermally conductive material sheet 110. Next, the peripheral region 113 of the thermally conductive material sheet 110 is sealed to form the chamber C, and the vacuuming process is performed on the chamber C, and the working fluid F is provided in the chamber C. After that, the chamber C is completely sealed, and the working fluid F fills the sealed chamber S. Therefore, the thermally conductive housing of the vapor chamber structure 100a of the present embodiment is manufactured through the thermally conductive material sheet 110, so that the vapor chamber structure 100a of the present embodiment may have a thinner thickness. In addition, the manufacturing of the vapor chamber structure 100a of the present embodiment is also relatively simple and low in cost.

It should be noted herein that in the following embodiments, reference numerals and some content of the foregoing embodiments are used, and same reference numerals are used to represent same or similar elements, and descriptions about same technical content are omitted. Reference may be made to the foregoing embodiments for the omitted portion, and the descriptions thereof are omitted in the following embodiments.

FIG. 1F is a schematic diagram of a vapor chamber structure according to an embodiment of the invention. For the sake of convenience, FIG. 1F is shown in a partially perspective manner. A vapor chamber structure 100a′ of the present embodiment is similar to the above-mentioned vapor chamber structure 100a, and the difference between the two is that a grid structure layer 130a′ of the present embodiment, is inclined at an angle relative to a thermally conductive material sheet 110. Further, fluid channels 132a′ located on an upper plane are arranged along a first direction Dr, and fluid channels 132a′ located on a lower plane are arranged along a second direction D2′, and the first direction D1′ is substantially perpendicular to the second direction D2′. Herein, the first direction D1′ is not parallel to a length direction (that is, an X axis) of the thermally conductive material sheet 110, and the second direction D2′ is not parallel to a width direction (that is, a Y axis) of the thermally conductive material sheet 110.

FIG. 1G is a schematic cross-sectional diagram of a vapor chamber structure according to an embodiment of the invention. A vapor chamber structure 100a″ of the present embodiment is similar to the above-mentioned vapor chamber structure 100a, and a difference between the two is that a capillary structure layer 120a′ of the present embodiment is only disposed on the first part 114 of the thermally conductive material sheet 110, and covers the top wall W1 and a part of the side wall W3, while a grid structure layer 130a′ is disposed on the second part 116 of the thermally conductive material sheet 110 and the capillary structure layer 120a′. At this time, a size of the grid structure layer 130a′ may be less than or equal to a size of the capillary structure layer 120a′. A heat source may be directly arranged on the first part 114 of the thermally conductive material sheet 110 provided with the capillary structure layer 120a′, so that heat may be effectively dissipated.

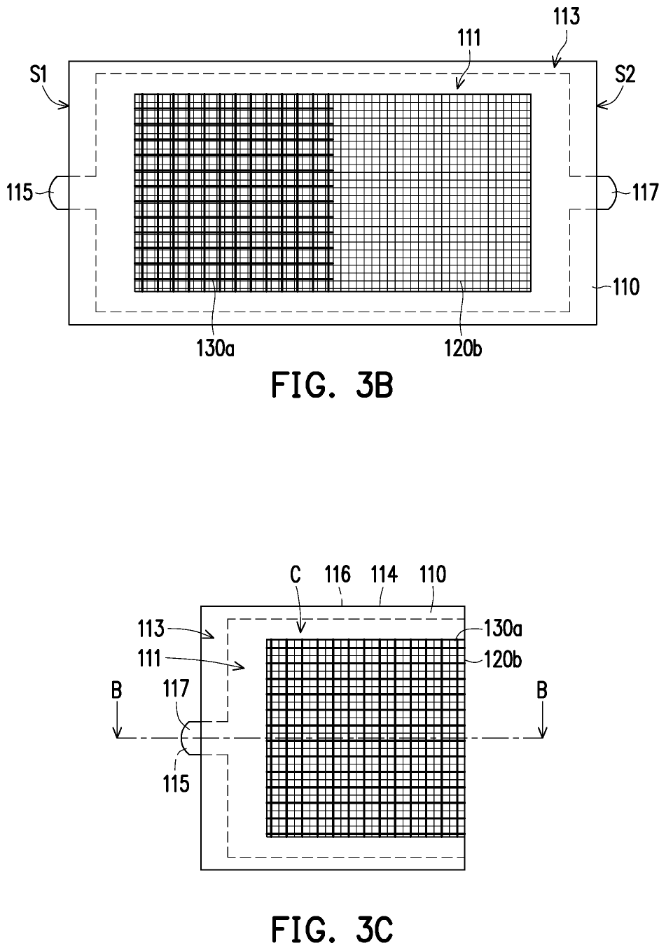

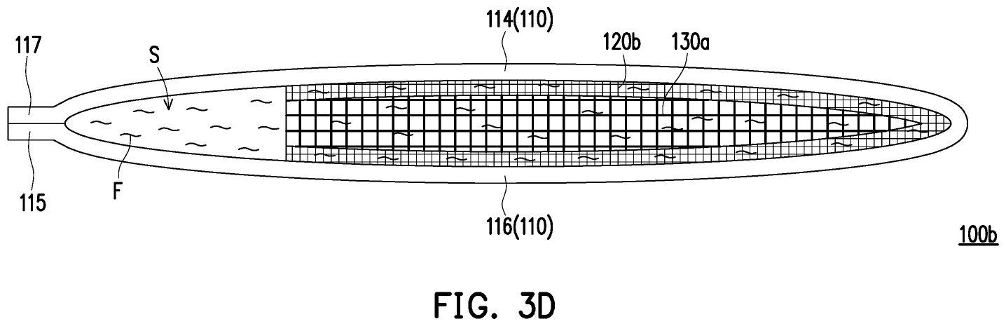

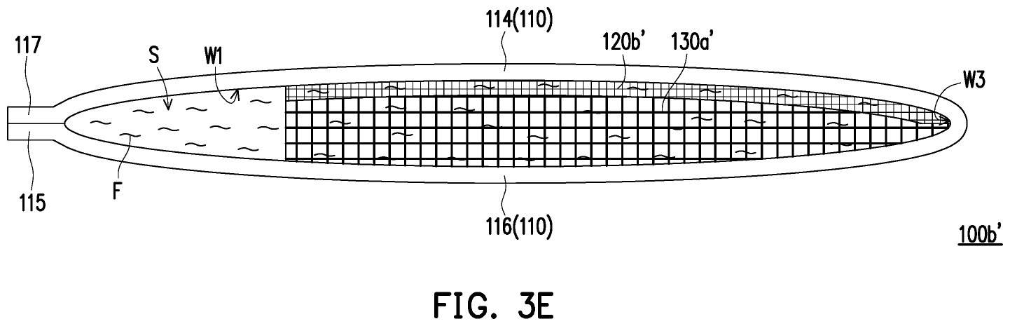

FIG. 3A to FIG. 3D are schematic diagrams of partial steps of a method for manufacturing a vapor chamber structure according to another embodiment of the invention. For the sake of convenience, FIG. 3C is shown in a partially perspective manner and FIG. 3D is a schematic cross-sectional diagram along a line B-B of FIG. 3C.

A method for manufacturing a vapor chamber structure 100b of the present embodiment is similar to the method for manufacturing the above-mentioned vapor chamber structure 100a, and a difference between the two is that after the steps of FIG. 1A, that is, after the thermally conductive material sheet 110 is provided, referring to FIG. 3A, a capillary structure layer 120b is formed in the configuration region 111 of the thermally conductive material sheet 110. Herein, the capillary structure layer 120b is embodied as a mesh structure layer, and a material of the mesh structure layer includes glass fiber, metal, ceramic, carbon, or organic plastic. For example, if a material of the mesh structure layer is glass fiber, a thickness of the glass fiber is about 100 microns, but the invention is not limited thereto.

Next, referring to FIG. 3B, a grid structure layer 130a is formed on the capillary structure layer 120b. A size of the grid structure layer 130a is less than or equal to half of a size of the capillary structure layer 120b. Herein, preferably, a hole of the mesh structure layer 120b is smaller than a hole of the grid structure layer 130a.

After that, referring to FIG. 3C and FIG. 3D, the thermally conductive material sheet 110 is folded in half, so that the grid structure layer 130a and the capillary structure layer 120b are sandwiched between the first part 114 and the second part 116 of the thermally conductive material sheet 110.

Next, still referring to FIG. 3C and FIG. 3D, the peripheral region 113 of the thermally conductive material sheet 110 is sealed to form a chamber C, and the grid structure layer 130a and the capillary structure layer 120b are located in the chamber C. Later, a vacuuming process is performed on the chamber C, and the working fluid F is provided in the chamber C. Finally, the chamber C is completely sealed to form a sealed chamber S, and cause the working fluid F to fill the sealed chamber S. So far, manufacturing of the vapor chamber structure 100b is completed.

In short, the capillary structure layer 120b of the present embodiment is embodied as the mesh structure layer. Therefore, not only the working fluid F may be transported through the capillary phenomenon, the working fluid F may further be allowed to pass through the mesh structure. The thermally conductive housing of the vapor chamber structure 100b of the present embodiment is manufactured by folding the thermally conductive material sheet 110 in half, so that the vapor chamber structure 100b of the present embodiment may have a thinner thickness. In addition, the manufacturing of the vapor chamber structure 100b of the present embodiment is also relatively simple and low in cost.

FIG. 3E is a schematic cross-sectional diagram of a vapor chamber structure according to an embodiment of the invention. A vapor chamber structure 100b′ of the present embodiment is similar to the above-mentioned vapor chamber structure 100b, and a difference between the two is that a capillary structure layer 120b′ of the present embodiment is only disposed on the first part 114 of the thermally conductive material sheet 110, and covers the top wall W1 and a part of the side wall W3, while a grid structure layer 130a′ is disposed on the second part 116 of the thermally conductive material sheet 110 and the capillary structure layer 120b′. At this time, a size of the grid structure layer 130a′ may be less than or equal to a size of the capillary structure layer 120b′. A heat source may be directly disposed on the first part 114 of the thermally conductive material sheet 110 provided with the capillary structure layer 120b′, so that heat may be effectively dissipated.

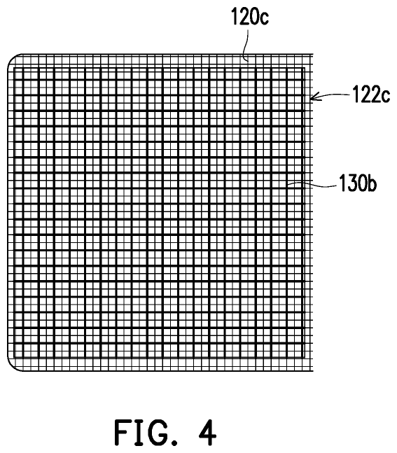

FIG. 4 is a schematic diagram of partial steps of a method for manufacturing a vapor chamber structure according to another embodiment of the invention. A method for manufacturing a vapor chamber structure of the present embodiment is similar to the method for manufacturing the above-mentioned vapor chamber structure 100b, and a difference between the two is that after the steps of FIG. 1A, that is, after the thermally conductive material sheet 110 is provided, referring to FIG. 4, a glass fiber bag is provided as a capillary structure layer 120c, and the glass fiber bag has an opening 122c. Next, the grid structure layer 130b is placed in the capillary structure layer 120c through the opening 122c. After that, following steps of FIG. 3C and FIG. 3D, manufacturing of the vapor chamber structure is completed.

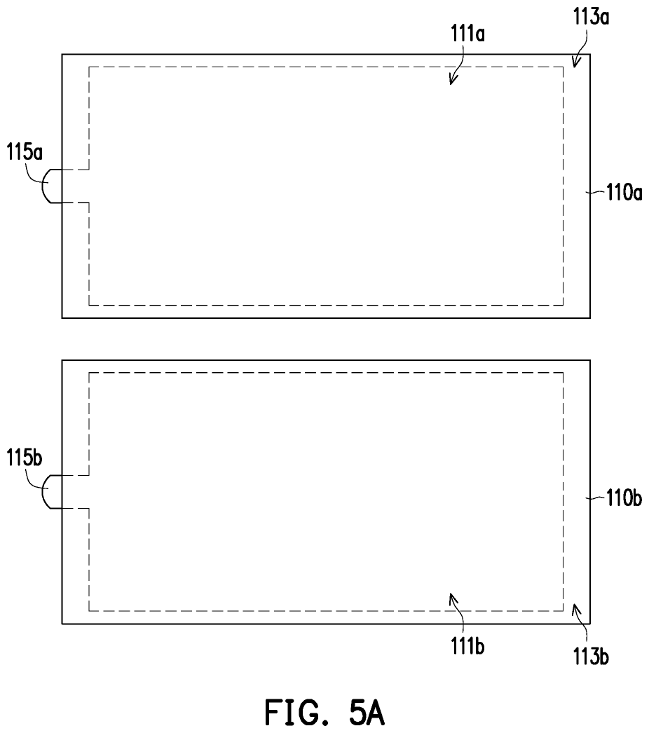

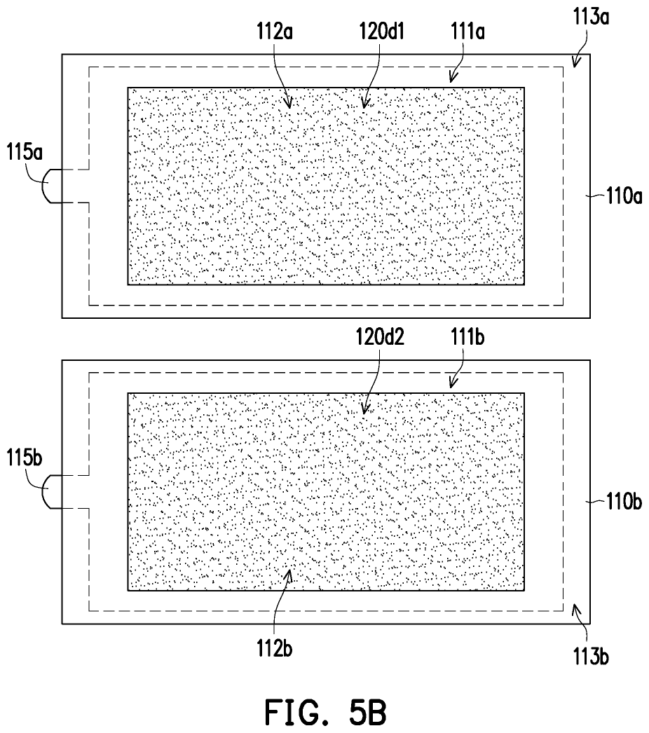

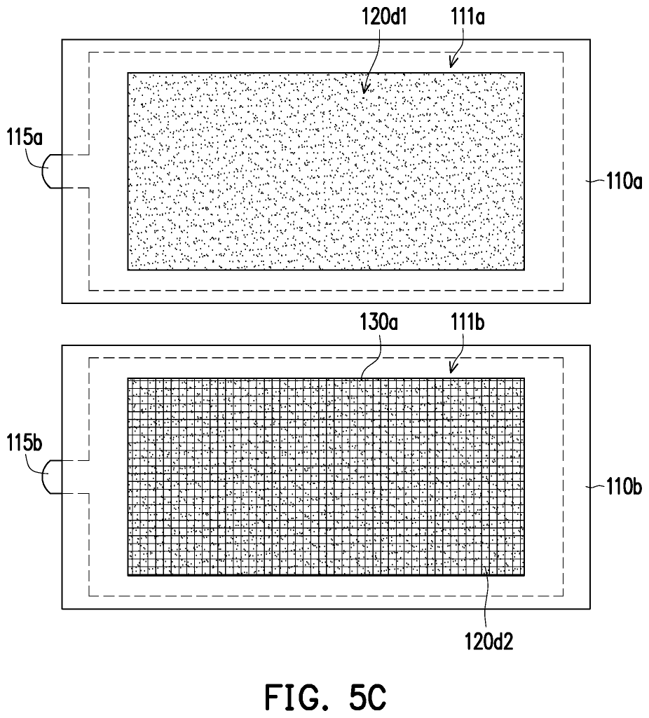

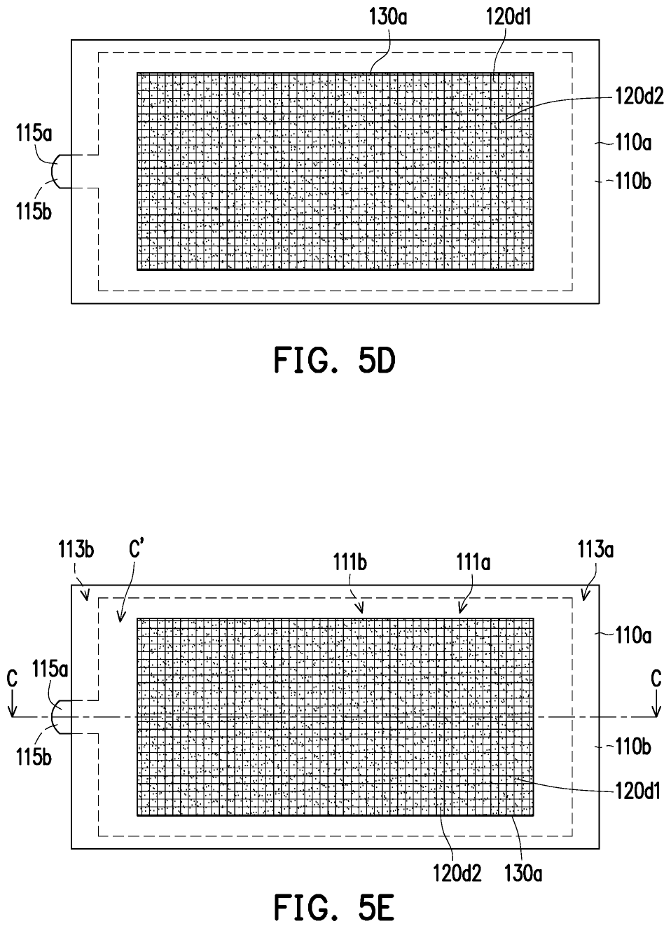

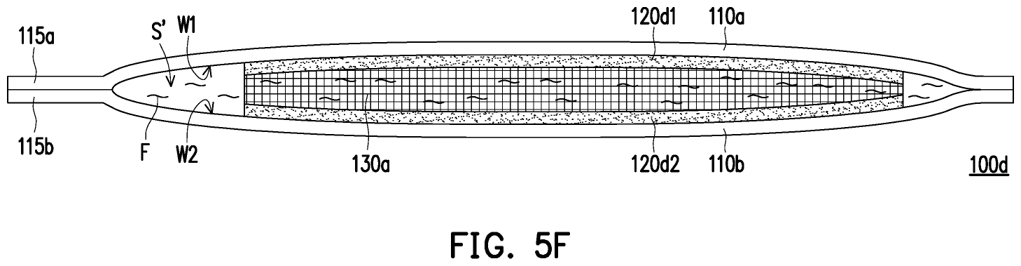

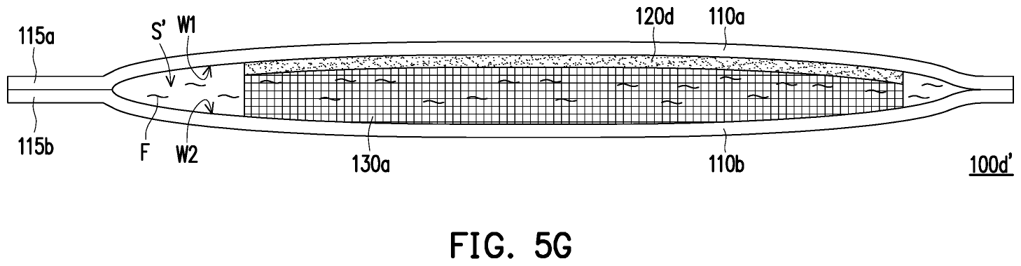

FIG. 5A to FIG. 5F are schematic diagrams of partial steps of a method for manufacturing a vapor chamber structure according to another embodiment of the invention. For the sake of convenience, FIG. 5D and FIG. 5E are shown in partial perspective manner and FIG. 5F is a schematic cross-sectional diagram along a line C-C of FIG. 5E.

A method for manufacturing a vapor chamber structure 100d (referring to FIG. 5F) of the present embodiment is similar to the method for manufacturing the above-mentioned vapor chamber structure 100a, and a difference between the two is that first referring to FIG. 5A, a first thermally conductive material sheet 110a and a second thermally conductive material sheet 110b are provided, and a size of the first thermally conductive material sheet 110a and a size of the second thermally conductive material sheet 110b are exactly the same. In detail, the first thermally conductive material sheet 110a of the present embodiment has a first configuration region 111a and a first peripheral region 113a surrounding the first configuration region 111a. The second thermally conductive material sheet 110b has a second configuration region 111b and a second peripheral region 113b surrounding the second configuration region 111b. In addition, the first thermally conductive material sheet 110a of the present embodiment has a first flap 115a, and the second thermally conductive material sheet 110b has a second flap 115b. Herein, a material of the first thermally conductive material sheet 110a and a material of the second thermally conductive material sheet 110b are, for example, metal or ceramic.

Next, referring to FIG. 5B, a first capillary structure layer 120d1 is formed in the first configuration region 111a of the first thermally conductive material sheet 110a, and a second capillary structure layer 120d2 is formed in the second configuration region 111b of the second thermally conductive material sheet 110b. Herein, a method for forming the first capillary structure layer 120d1 and the second capillary structure layer 120d2 is, for example, respectively performing an etching process, an electroplating process, a printing process, a laser process, or a sintering process on the first thermally conductive material sheet 110a and the second thermally conductive material sheet 110b, and the first capillary structure layer 120d1 is formed on a first surface 112a of the first thermally conductive material sheet 110a, and a second capillary structure layer 120d2 is formed on a second surface 112b of the second thermally conductive material sheet 110b.

Next, referring to FIG. 5C, a grid structure layer 130a is formed on the second capillary structure layer 120d2. A size of the grid structure layer 130a is less than a size of the second thermally conductive material sheet 110b, and the size of the grid structure layer 130a may be less than or equal to a size of the second capillary structure layer 120d2. Herein, a structure of the grid structure layer 130a is the same as the structure shown in FIG. 2A and FIG. 2B. A material of the grid structure layer 130a includes glass fiber, metal, ceramic, carbon, or organic plastic. In another embodiment, the grid structure layer 130b may further be as shown in FIG. 2C, which still belongs to the protective scope of the invention.

Next, referring to FIG. 5D, the first thermally conductive material sheet 110a is overlapped on the second thermally conductive material sheet 110b, so that the grid structure layer 130a is sandwiched between the first capillary structure layer 120d1 and the second capillary structure layer 120d2. At this time, the first flap 115a of the first thermally conductive material sheet 110a overlaps the second flap 115b of the second thermally conductive material sheet 110b.

After that, referring to both FIG. 5E and FIG. 5F, after the first thermally conductive material sheet 110a is overlapped on the second thermally conductive material sheet 110b, the first peripheral region 113a of the first thermally conductive material sheet 110a and the second peripheral region 113b of the second thermally conductive material sheet 110b are sealed to form a chamber C′. The grid structure layer 130a, the first capillary structure layer 120d1, and the second capillary structure layer 120d2 are located in the chamber C′. Herein, a method for sealing the first peripheral region 113a and the second peripheral region 113b is, for example, a mechanical clamping process, a welding process, a soft soldering process, a diffusion bonding process, or an adhering process.

Next, referring to both FIG. 5E and FIG. 5F, a vacuuming process is performed on the chamber C′, and a working fluid F is provided in the chamber C′. More particular, the vacuuming process is performed on the chamber C′ from a space between the first flap 115a and the second flap 115b, and the working fluid F is provided in the chamber C′ from the space between the first flap 115a and the second flap 115b. The chamber C′ is completely sealed to form a sealed chamber S′, and the working fluid F fills the sealed chamber S′. Herein, the space between the first flap 115a and the second flap 115b is sealed to completely seal the chamber C′. A method for completely sealing the chamber C′ includes a mechanical clamping process, a welding process, a soft soldering process, or an adhering process, and the working fluid F is, for example, water. So far, manufacturing of the vapor chamber structure 100d is completed.

In terms of the structure, still referring to FIG. 5F, the vapor chamber structure 100d of the present embodiment includes a thermally conductive housing formed by sealing the first thermally conductive material sheet 110a and the second thermally conductive material sheet 110b that overlap each other, the capillary structure layer, the grid structure layer 130a, and the working fluid F. The thermally conductive housing has the sealed chamber S′, and the pressure in the sealed chamber S′ is lower than the standard atmospheric pressure. Therefore, a boiling temperature of the working fluid F (for example, water) herein is about 60° C. Herein, a material of the thermally conductive housing is, for example, metal or ceramic. The capillary structure layer is disposed in the sealed chamber S′, and includes the first capillary structure portion (that is, the first capillary structure layer 120d1) and the second capillary structure portion (that is, the second capillary structure layer 120d2) to transport the working fluid F through the capillary phenomenon. The sealed chamber S′ has the top wall W1 and the bottom wall W2 opposite to each other, and the first capillary structure portion (that is, the first capillary structure layer 120d1) is located on the top wall W1, and the second capillary structure portion (that is, the second capillary structure layer 120d2) is located on the bottom wall W2. The grid structure layer 130a is disposed in the sealed chamber S′ and sandwiched between the first capillary structure portion (that is, the first capillary structure layer 120d1) and the second capillary structure portion (that is, the second capillary structure layer 120d2), to prevent the top wall W1 from directly contacting the bottom wall W2 and allow the working fluid F to pass. A size of the grid structure layer 130a is less than or equal to half of a size of the capillary structure layer, and a material of the grid structure layer 130a includes glass fiber, metal, ceramic, carbon, or organic plastic. The working fluid F fills the sealed chamber S′, and the working fluid F is, for example, water. Preferably, an overall thickness of the vapor chamber structure 100d of the present embodiment is less than 300 microns, preferably, less than or equal to 0.25 mm.

In short, the thermally conductive housing of the vapor chamber structure 100d of the present embodiment is formed by sealing the first thermally conductive material sheet 110a and the second thermally conductive material sheet 110b that overlap each other. Therefore, the vapor chamber structure 100d of the present embodiment may have a thinner thickness. In addition, the manufacturing of the vapor chamber structure 100d of the present embodiment is also relatively simple and low in cost.

FIG. 5G is a schematic cross-sectional diagram of a vapor chamber structure according to an embodiment of the invention. A vapor chamber structure 100d′ of the present embodiment is similar to the above-mentioned vapor chamber 100d, and a difference between the two is that a capillary structure layer 120d of the present embodiment is only one layer and disposed on the first thermally conductive material sheet 110a, and the grid structure layer 130a is disposed on the second thermally conductive material sheet 110b. At this time, a size of the grid structure layer 130a may be smaller than or equal to a size of the capillary structure layer 120d. A heat source may be directly arranged on a first thermally conductive material sheet 110a provided with the capillary structure layer 120d, so that heat may be effectively dissipated.

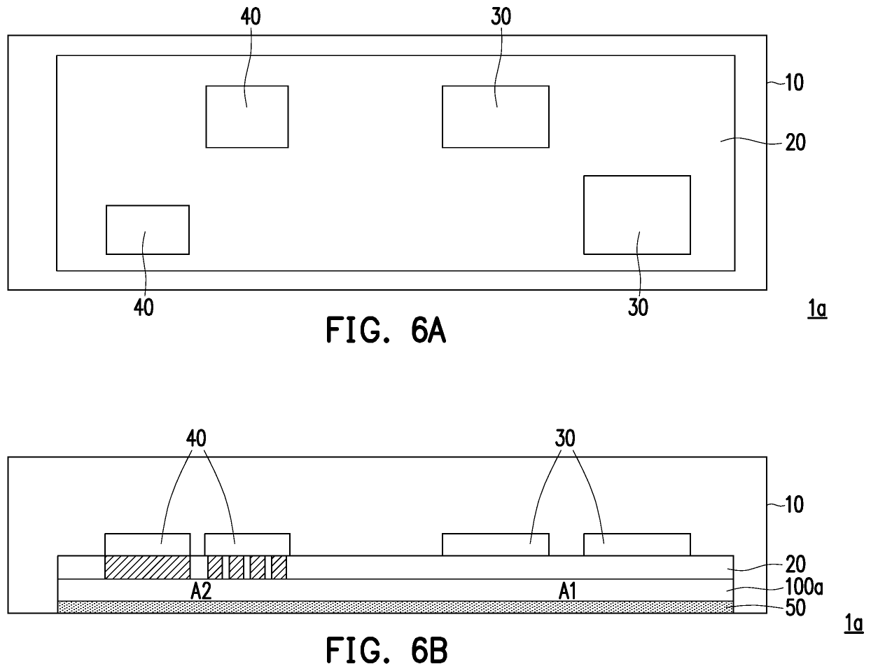

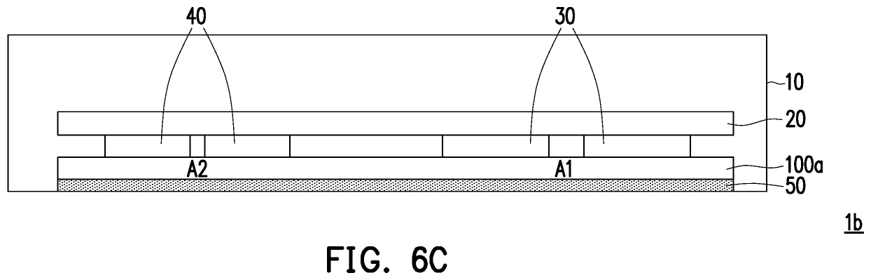

FIG. 6A and FIG. 6B are a schematic top diagram and a schematic cross-sectional diagram of an electronic device by using the vapor chamber structure of the invention. FIG. 6C is a schematic cross-sectional diagram of another electronic device by using the vapor chamber structure of the invention. For the sake of convenience, FIG. 6A omits some members and is shown in a perspective manner.

In terms of the application, referring to both FIG. 6A and FIG. 6B, in the present embodiment, an electronic product 1a is, for example, a mobile phone and includes the vapor chamber structure 100a shown in FIG. 1E, a housing 10, a circuit board 20, a plurality of non-heat-generating devices 30 (such as a passive element), a plurality of heat-generating chips 40, and an adhesive layer 50. The vapor chamber structure 100a is fixed on the housing 10 through the adhesive layer 50 and is located between the circuit board 20 and the adhesive layer 50. The non-heat-generating device 30 and the heat-generating chip 40 are respectively configured on the circuit board 20, and the heat-generating chip 40 is electrically connected to the circuit board 20. The non-heat-generating device 30 may be correspondingly located in a condensation region A1 of the vapor chamber structure 100a, and the heat-generating chip 40 may be correspondingly located in an evaporation region A2 of the vapor chamber structure 100a. For example, in FIG. 6B, it is shown that a metal block or a through hole for filling metal is disposed in the circuit board to connect the heat-generating chip to the evaporation region of the vapor chamber structure, so that waste heat is transported to the condensation region. In another embodiment, referring to FIG. 6C, the non-heat-generating device 30 and the heat-generating chip 40 of an electronic product 1b may be located between the circuit board 20 and the vapor chamber structure 100a, which still belongs to the protective scope of the invention. Because the vapor chamber structure 100a of the present embodiment has a less thickness, the vapor chamber structure is adapted for being placed in the electronic products 1a and 1b to assist in heat dissipation of the electronic products 1a and 1b.

Based on the above, in the method for manufacturing the vapor chamber structure of the invention, the grid structure layer and the capillary structure layer are sandwiched between the first part and the second part of the thermally conductive material sheet by folding the thermally conductive material sheet. Next, the peripheral region of the thermally conductive material sheet is sealed to form the chamber, and the vacuuming process is performed on the chamber, and the working fluid is provided in the chamber. After that, the chamber is completely sealed to cause the working fluid to fill the sealed chamber. Therefore, the thermally conductive housing of the vapor chamber structure of the invention is manufactured through the thermally conductive material sheet, so that the vapor chamber structure of the invention may have a thinner thickness. In addition, the manufacturing of the vapor chamber structure of the invention is also relatively simply and low in cost.

Although the present invention is disclosed in the embodiments above, the present invention is not limited thereto. A person of ordinary skill in the art may make a little variations and modifications without departing from the spirit and scope of the present invention. Therefore, the protection scope of the present invention should be subject to the claims.

What is claimed is:

1. A vapor chamber structure, comprising:
a thermally conductive housing having a sealed chamber, wherein a pressure in the sealed chamber is lower than a standard atmospheric pressure;
a capillary structure layer disposed in the sealed chamber;
a grid structure layer disposed in the sealed chamber and arranged along a first direction, wherein a size of the grid structure layer is less than or equal to a size of the capillary structure layer; and
a working fluid filling the sealed chamber.

2. The vapor chamber structure according to claim 1, wherein the thermally conductive housing is formed by sealing a folded thermally conductive material sheet.

3. The vapor chamber structure according to claim 2, wherein a size of the grid structure layer is less than or equal to half of the size of the capillary structure layer.

4. The vapor chamber structure according to claim 3, wherein the capillary structure layer comprises a first capillary structure portion, a second capillary structure portion, and a third capillary structure portion, the sealed chamber has a top wall and a bottom wall opposite to each other and a side wall connecting the top wall to the bottom wall, the first capillary structure portion is located on the top wall, the second capillary structure portion is located on the bottom wall, the third capillary structure portion is located on the side wall, and the grid structure layer is sandwiched between the first capillary structure portion and the second capillary structure portion.

5. The vapor chamber structure according to claim 1, wherein the thermally conductive housing is formed by sealing a first thermally conductive material sheet and a second thermally conductive material sheet that overlap each other.

6. The vapor chamber structure according to claim 5, wherein a size of the grid structure layer is less than or equal to half of the size of the capillary structure layer.

7. The vapor chamber structure according to claim 6, wherein the capillary structure layer comprises a first capillary structure portion and a second capillary structure portion, the sealed chamber has a top wall and a bottom wall opposite to each other, the first capillary structure portion is located on the top wall, the second capillary structure portion is located on the bottom wall, and the grid structure layer is sandwiched between the first capillary structure portion and the second capillary structure portion.

8. The vapor chamber structure according to claim 1, wherein the capillary structure layer is a surface microstructure layer of the thermally conductive housing.

9. The vapor chamber structure according to claim 1, wherein the capillary structure layer is a mesh structure layer and a hole of the mesh structure layer is smaller than a hole of the grid structure layer.

10. The vapor chamber structure according to claim 9, wherein a material of the mesh structure layer comprises glass fiber, metal, ceramic, carbon, or organic plastic.

11. The vapor chamber structure according to claim 1, wherein the grid structure layer comprises a plurality of fluid channels, and the plurality of fluid channels are arranged on a same plane at equal intervals along the first direction.

12. The vapor chamber structure according to claim 1, wherein the grid structure layer comprises a plurality of fluid channels, and the plurality of fluid channels are arranged on different planes in a matrix along the first direction and a second direction perpendicular to the first direction.

13. The vapor chamber structure according to claim 1, wherein a material of the grid structure layer comprises glass fiber, metal, ceramic, carbon, or organic plastic.

14. The vapor chamber structure according to claim 1, wherein the working fluid comprises water.

15. The vapor chamber structure according to claim 1, wherein a material of the thermally conductive housing comprises metal or ceramic.

16. A method for manufacturing a vapor chamber structure, comprising:
providing a thermally conductive material sheet, wherein the thermally conductive material sheet has a configuration region and a peripheral region surrounding the configuration region;
forming a capillary structure layer on the configuration region of the thermally conductive material sheet;
forming a grid structure layer on the capillary structure layer, wherein a size of the grid structure layer is less than or equal to half of a size of the capillary structure layer;
folding the thermally conductive material sheet in half to cause the grid structure layer and the capillary structure layer to be sandwiched between a first part and a second part of the thermally conductive material sheet;
after folding the thermally conductive material sheet in half, sealing the peripheral region of the thermally conductive material sheet to form a chamber, wherein the grid structure layer and the capillary structure layer are located in the chamber;
performing a vacuuming process on the chamber, and providing a working fluid in the chamber; and
completely sealing the chamber to form a sealed chamber and cause the working fluid to fill the sealed chamber.

17. The method for manufacturing the vapor chamber structure according to claim 16, wherein the thermally conductive material sheet has a first side and a second side opposite to each other and two flaps, the two flaps are respectively connected to the first side and the second side and disposed corresponding to each other, and the configuration region is connected to the two flaps, and
the vacuuming process is performed on the chamber from a space between the two flaps and the working fluid is provided in the chamber from the space between the two flaps; and
the space between the two flaps is sealed to completely seal the chamber.

18. The method for manufacturing the vapor chamber structure according to claim 16, wherein a method for forming the capillary structure layer comprises performing an etching process, an electroplating process, a printing process, a laser process, or a sintering process on the thermally conductive material sheet to form the capillary structure layer on a surface of the thermally conductive material sheet.

19. The method for manufacturing the vapor chamber structure according to claim 16, wherein the capillary structure layer is a mesh structure layer and a hole of the mesh structure layer is smaller than a hole of the grid structure layer.

20. The method for manufacturing the vapor chamber structure according to claim 19, wherein a material of the mesh structure layer comprises glass fiber, metal, ceramic, carbon, or organic plastic.

21. The method for manufacturing the vapor chamber structure according to claim 16, wherein the grid structure layer comprises a plurality of fluid channels, and the plurality of fluid channels are arranged on a same plane at equal intervals or arranged on different planes in a matrix.

22. The method for manufacturing the vapor chamber structure according to claim 16, wherein a material of the grid structure layer comprises glass fiber, metal, ceramic, carbon, or organic plastic.

23. The method for manufacturing the vapor chamber structure according to claim 16, wherein a method for completely sealing the chamber comprises a mechanical clamping process, a welding process, a soft soldering process, a diffusion bonding process, or an adhering process.

24. The method for manufacturing the vapor chamber structure according to claim 16, wherein the working fluid comprises water.

25. The method for manufacturing the vapor chamber structure according to claim 16, wherein a material of the thermally conductive material sheet comprises metal or ceramic.

26. A method for manufacturing a vapor chamber structure, comprising:
providing a first thermally conductive material sheet and a second thermally conductive material sheet, wherein the first thermally conductive material sheet has a first configuration region and a first peripheral region surrounding the first configuration region, and the second thermally conductive material sheet has a second configuration region and a second peripheral region surrounding the second configuration region;
forming a first capillary structure layer in the first configuration region of the first thermally conductive material sheet, and forming a second capillary structure layer in the second configuration region of the second thermally conductive material sheet;
forming a grid structure layer on the second capillary structure layer, wherein a size of the grid structure layer is less than a size of the second thermally conductive material sheet;
overlapping the first thermally conductive material sheet on the second thermally conductive material sheet to cause the grid structure layer to be sandwiched between the first capillary structure layer and the second capillary structure layer;
after overlapping the first thermally conductive material sheet on the second thermally conductive material sheet, sealing the first peripheral region of the first thermally conductive material sheet and the second peripheral region of the second thermally conductive material sheet to form a chamber, wherein the grid structure layer, the first capillary structure layer, and the second capillary structure layer are located in the chamber;
performing a vacuuming process on the chamber, and providing a working fluid in the chamber; and
completely sealing the chamber to form a sealed chamber and cause the working fluid to fill the sealed chamber.

27. The method for manufacturing the vapor chamber structure according to claim 26, wherein the first thermally conductive material sheet has a first flap, and the second thermally conductive material sheet has a second flap, and
when the first thermally conductive material sheet is overlapped on the second thermally conductive material sheet, the first flap is overlapped on the second flap,
the vacuuming process is performed on the chamber from a space between the first flap and the second flap, and the working fluid is provided in the chamber from the space between the first flap and the second flap; and
the space between the first flap and the second flap is sealed to completely seal the chamber.

28. The method for manufacturing the vapor chamber structure according to claim 26, wherein a method for forming the first capillary structure layer and the second capillary structure layer comprises respectively performing an etching process, an electroplating process, a printing process, a laser process, or a sintering process on the first thermally conductive material sheet and the second thermally conductive material sheet to form the first capillary structure layer on a first surface of the first thermally conductive material sheet and form the second capillary structure layer on a second surface of the second thermally conductive material sheet.

29. The method for manufacturing the vapor chamber structure according to claim 26, wherein the grid structure layer comprises a plurality of fluid channels, and the plurality of fluid channels are arranged on a same plane at equal intervals or arranged on different planes in a matrix.

30. The method for manufacturing the vapor chamber structure according to claim 26, wherein a method for completely sealing the chamber comprises a mechanical clamping process, a welding process, a soft soldering process, a diffusion bonding process, or an adhering process.

31. The method for manufacturing the vapor chamber structure according to claim 26, wherein a material of the grid structure layer comprises glass fiber, metal, ceramic, carbon, or organic plastic.

32. The method for manufacturing the vapor chamber structure according to claim 26, wherein the working fluid comprises water.

33. The method for manufacturing the vapor chamber structure according to claim 26, wherein a material of the first thermally conductive material sheet comprises metal or ceramic.

34. The method for manufacturing the vapor chamber structure according to claim 26, wherein a material of the second thermally conductive material sheet comprises metal or ceramic.
